(19) United States
(12) Patent Application Publication
(10) Pub. No.: US 2007/0263676 A1
(43) Pub. Date: Nov. 15, 2007

(54) System Comprising a Low Phase Noise Waveguide Laser, a Method of Its Manufacturing and Its Use

(75) Inventors: Martijn Beukema, Brussels (BE); Christian Vestergaard Poulsen, Farum (DK); Jens Engholm Pedersen, Birkerod (DK); Poul Varming, Copenhagen O (DK)

Correspondence Address: BUCHANAN, INGERSOLL & ROONEY PC, POST OFFICE BOX 1404, ALEXANDRIA, VA, 22313-1404, US

(73) Assignee: KOHERAS A/S, Bikerød (DK)

(21) Appl. No.: 11/629,519

(22) PCT Filed: Jun. 21, 2005
(86) PCT No.: PCT/DK05/00415

§ 371 Date: Jul. 17, 2007

Related U.S. Application Data
(60) Provisional application No. 60/582,061, filed on Jun. 24, 2004.

(30) Foreign Application Priority Data
Jun. 24, 2004 (DK) PA 2004 01027

(51) Int. Cl. H01S 3/0941; H01S 3/063; H01S 5/14; H01S 3/094

(52) U.S. Cl. 372/6; 372/70; 372/72; 372/75

(57) ABSTRACT

The invention relates to a system comprising a waveguide laser for exciting laser light at a lasing wavelength λₛ and a pump for pumping the waveguide laser at a pumping wavelength λₚ. The invention further relates to a method of providing such a system and its use. The object of the present invention is to provide a system comprising a waveguide laser with a reduced phase noise. The problem is solved in that the pump is a single frequency laser. The invention may e.g. be used in systems where an ultra-low phase noise and/or linewidth is required, e.g. in LIDAR or interferometric systems.

### TECHNICAL FIELD

The invention relates generally to lasers and more particularly to waveguide lasers, e.g. Bragg grating based optical waveguide lasers with reduced phase noise characteristics.

The invention relates specifically to a system comprising a waveguide laser for exciting laser light at a lasing wavelength λₛ and a pump for pumping the waveguide laser at a pumping wavelength λₚ.

The invention furthermore relates to a method of providing a system for exciting laser light at a lasing wavelength λₛ.

The invention furthermore relates to: Use of a system according to the invention or a system obtainable by the method according to the invention.

The invention may e.g. be useful in applications where low phase noise and/or an ultra-low linewidth is required, e.g. in LIDAR or interferometric systems.

### BACKGROUND ART

The following account of the prior art relates to one of the areas of application of the present invention, optical fibre laser systems.

Bragg grating based optical fibre lasers may e.g. produced by UV-imprinting a Bragg grating in a photo sensitive fibre doped with an optically active agent such as a rare earth ion (e g erbium, ytterbium, and others) as described in a variety of sources, e.g. WO-98/36300. Bragg grating based optical fibre lasers may combine attractive features such as stable single mode operation, narrow linewidth and long coherence length, tuning capability, wavelength selectability, mechanical robustness, small size, low power consumption, and immunity to electromagnetic interference (EMI).

For a number of applications a long coherence length or equivalently a narrow linewidth or low frequency/phase noise is desirable. However noise from semiconductor pump lasers, is directly coupled to the frequency and intensity noise of the fibre laser, depending on the transfer filter function of the active medium, resulting in frequency jitter, a larger linewidth and an increased relative intensity noise (RIN). In order to stabilise the fibre laser frequency and enhance its coherence length it is thus necessary to reduce or eliminate the noise of the semiconductor pump laser.

Commercially available semiconductor pump lasers can operate in either a single or multi mode. In both configurations, a fibre Bragg grating is used as feedback to stabilise the laser signal.

Single mode operation of the laser chip can for example be achieved when a fibre Bragg grating (FBG) with a lower centre wavelength, than the free running laser, is used (cf. e.g. “Detuning characteristics of fibre Bragg grating stabilized 980 nm pump lasers”; S. Mohrdiek, M. Achtenhagen, C. Harder, A. Hardy, OFC Conf. Baltimore, Md., 2000, pp 168-170), combined with placing the FBG close to the laser output facet (cf. e.g. A. Othonos, K. Kali, in “Fiber Bragg Gratings”, p. 253, 1999, Artech House, referred to as [Othonos et al.] in the following). Choosing the parameters of the FBG carefully, the SCL can also be forced into one stable longitudinal solitary laser-chip mode, still comprising many external cavity modes. This is e.g. shown for a commercially available semiconductor laser (SCL) with a feedback FBG (e.g. Product LU0976M from Lumics GmbH, Berlin, Germany).

Multi mode pump lasers are operating in the so called Coherence Collapse regime (see for example D. Lenstra et al., ‘Coherence Collapse in single-mode semiconductor lasers due to optical feedback’, IEEE J. Quantum Electron., vol. QE-21, pp. 674-679, June 1985). An advantage of the laser operating in the coherence collapse state is that the large number of modes and their lack of coherence cancel out low frequency power fluctuations associated with mode hopping (cf. e.g. [Othonos et al.]). This results in a stable output power, which is of importance for rare-earth doped fibre amplifier systems.

The erbium/ytterbium co-doped fibre laser is known in the field for very low levels of relative intensity noise (RIN), which is much lower than that of the erbium doped fibre laser. The linewidth of this laser however is broader.

It is therefore of interest to find a method of combining low relative intensity noise with narrow linewidth for fibre lasers.

To reduce the optical intensity- and phase-noise in fibre lasers two different feed-back mechanisms have previously been used.

A first method consists of RIN suppression with a negative electronic feedback loop. This is for example described in the article “Low-noise Narrow-Linewidth Fiber laser at 1550 nm”, C. Spiegelberg et al., Journal of Lightwave Technology, Vol. 22, No. 1, January 2004.

The other method is frequency stabilization by frequency locking techniques for example as mentioned in J. Phys. D: Appl. Phys. 34 (2001) 2396-2407.

U.S. Pat. No. 5,870,417 describes a waveguide DBR laser source for stabilized wavelength operation and suppressed longitudinal mode hopping. An optical amplifier device comprising a modulated transmitter in the form of a DBR fiber laser operating at 1.5 μm in a single longitudinal mode is coupled to an Er-doped fiber amplifier. In an embodiment, the pump source coupled to the fiber amplifier is also configured as a fiber DBR laser operating in cw mode at 980 nm or 1480 nm. The waveguide DBR laser is comprised of at least one semiconductor gain element in combination with either an optical fiber having a waveguide grating, or sets of these, functioning as a resonant cavity end reflection for laser operation.

U.S. Pat. No. 6,487,006 describes an optical amplifier for amplifying a single mode communications signal, the optical amplifier comprising a length of co-doped Er/Yb double clad fibre comprising an inner cladding supporting a multimode pump signal and a rare earth doped core for co-propagating the single mode communications signal as well as a multi mode pump signal.

U.S. Pat. No. 5,305,335 describes a single (longitudinal) mode fibre laser pumped by a laser pump, e.g. a diode laser.

U.S. Pat. No. 6,574,262 describes a large area single mode waveguide laser comprising an optical waveguide with a Bragg grating and a semiconductor pump.

### DISCLOSURE OF INVENTION

The coherence length and the frequency/phase noise properties of Bragg-grating based fibre lasers are influenced negatively by instabilities in the pump output power as well as mode-behaviour.

Commercially available semiconductors with weak fibre Bragg gratings (with typically 4-15% reflectivity) as external feedback are designed to operate in the coherence collapse regime. This configuration allows many external cavity modes in several chip cavity modes. There are typically over 6 strong solitary laser chip modes with a mode spacing of around 150 GHz. The distance between the high reflection laser facet and the position of the FBG defines the spacing of the external cavity modes. With a distance of typically over 1 m, the mode spacing is typically less than 1 GHz. Even though the total output intensity of the laser is stable, the chaotic mode behaviour, due to mode competition, induces amplitude noise of both the individual solitary laser chip and external cavity modes.

The absorption cross section of the optically active medium is a function of the wavelength and has a given bandwidth depending on the medium. The pump laser light is absorbed by the active medium of the fibre laser and the lasing will start above the threshold level. Fluctuations of both the amplitude and the frequency of the pump laser modes will be transferred directly to the fibre laser active medium. This noise induces absorption fluctuations. The absorption is directly related with the refractive index via the Kramers-Kronig relations. Distortions will therefore modulate the refractive index and result in frequency jitter of the fibre laser.

For example in case of a fibre laser with an erbium-ytterbium (Er—Yb) co-doped active medium, the ytterbium shows the strongest absorption peak around 976 nm with a narrow 3 dB bandwidth of a couple of nanometres. To pump the fibre laser, the operating wavelength of the SCL is typically chosen in this range. The problem now is both mode-competition noise and the number of solitary cavity modes, covering the steep slope of the ytterbium absorption band. This induces strong absorption fluctuations in the ytterbium system. First of all fluctuations in the absorption can be directly related to a change in the refractive index. Secondly the phonon-relaxation of the Erbium ions causes a temperature increase. Temperature fluctuations will result in a change of refractive index due to the thermo-optic effect. These index changes induce frequency jitter and an increased phase noise limited linewidth.

Another problem with the prior art is that there is no laser known in the field, which combines the ultra low phase noise limited linewidth with a shot-noise limited RIN. For example erbium doped lasers do have a very low phase noise limited linewidth, but these lasers have a high relative intensity noise (typically lower than 1 kHz and −90 dB/Hz respectively) in comparison with Er/Yb-doped lasers.

The object of the present invention is to provide a system comprising a waveguide laser with a reduced phase noise.

It is still another object of the present invention to provide a system comprising a waveguide laser with a reduced line width.

It is still another object of the present invention to provide a system comprising a waveguide laser with both low phase noise and a reduced line width.

It is still another object of the present invention to provide a system comprising a waveguide laser with a low phase noise as well as a low relative intensity noise (RIN).

Further objects of the present invention are to provide a method of manufacturing and use of such an optical waveguide laser system.

The objects of the invention are achieved by the invention described in the accompanying claims and as described in the following.

An object of the invention is achieved according to the invention by providing a system comprising a waveguide laser for exciting laser light at a lasing wavelength λₛ and a pump for pumping the waveguide laser at a pumping wavelength λₚ wherein the pump is a single frequency laser.

The term ‘single frequency pump laser’ is in the present context taken to mean a laser that only operates in one mode at a given time (i.e. a pump laser that exhibits mode hopping is included). By operation in ‘one mode at a given time’ is meant that—at a specific point in time—only light having one specific combination of longitudinal and transversal (spatial) mode configuration and polarization state is excited.

In a preferred embodiment, the pump laser is a narrow linewidth, single frequency pump laser. The term ‘a narrow linewidth, single frequency pump laser’ is in the present context taken to mean a laser having a linewidth of less than 100 MHz, such as less than 10 MHz, such as less than 1 MHz such as less than 100 kHz and operating in a single longitudinal mode. This has the advantage that there is no significant mode competition which strongly reduces the amplitude noise of this laser type.

Using a single frequency pump laser in combination with a waveguide laser, makes it possible to obtain a laser system which shows a decreased phase noise.

The present invention further makes it possible to obtain a laser system with both low phase noise and shot noise limited RIN.

The present invention further makes it possible to provide a combination of the features of a narrow linewidth and a very low RIN level in one laser system. This can be achieved by combining a narrow linewidth, single frequency pump laser with a waveguide laser exhibiting low RIN in a system according to the invention.

In an embodiment, said single frequency pump laser is a semiconductor laser. Semiconductor lasers are available in a many varieties, based on a mature technology and are relatively economic. Alternatively, a solid state, crystal-based laser (e.g. a YAG-laser) could be used. Alternatively a waveguide laser based on a micro-structured fibre could be used as pump potentially providing a more stable pump with better characteristics.

The telecommunication market mainly drives the development of the external cavity semiconductor lasers (EC-SCL). The pump diodes are mainly used in optical amplifier systems and are thoroughly tested on reliability. These systems require a constant output power of the laser diode. It is therefore of interest to operate the pump diodes in the coherent collapse regime, which provides stable output power, but maintains the mode competition between the many modes, which are not specified.

Single frequency laser diodes are mainly used for analytical and sensor applications and are not known as pump source for fibre lasers due to their higher price.

In an embodiment, said single frequency pump laser is an external cavity laser. Using an external cavity has the advantage of stabilizing the output power. In a preferred embodiment, a stable semiconductor laser (SCL) is used. The term ‘stable’ is in the present context taken to mean that the ‘frequency and intensity’ of the SCL-laser is stable, i.e. that the laser has a low frequency jitter and shows an absence or a low frequency of mode hops, the latter being e.g. smaller than 20 Hz, such as smaller than 10 Hz, such as smaller than 1 Hz, such as smaller than 0.1 Hz.

A fibre laser pumped with a stable single frequency pump, for example an external cavity semiconductor laser operating in a stable single mode, which can be either a chip or an external cavity mode. This will eliminate the mode competition between the cavity modes and therefore the main source of amplitude noise. This results in a narrow linewidth of the fibre laser. Experimental results are shown in the accompanying drawings.

In an embodiment, said external cavity comprises an optical waveguide with a Bragg grating. This has the advantage of providing a large design freedom regarding the reflectivity and wavelength of the reflective element in the external cavity. Further, it can reduce the risk of ‘drop-out’ of the laser signal.

In an embodiment, the optical waveguide of the external cavity is a polarization maintaining optical waveguide. This has the advantage that the polarisation direction of the pump light is maintained over the length of the optical waveguide, which reduces the risk of introducing noise into the waveguide laser due to mechanical vibrations (incl. acoustic).

In an embodiment, said waveguide laser is a Bragg grating laser. This has the advantage of providing a laser with an easily selective wavelength. A Bragg grating waveguide laser is in the present context taken to mean a waveguide laser comprising at least one Bragg grating.

In an embodiment, said waveguide laser is a distributed feedback laser. This has the advantage of providing a DFB laser—i.e. a laser comprising a length of optical waveguide comprising optically active material wherein a Bragg grating comprising a phase shift is dispersed—with a reduced mode hop frequency.

In an embodiment, the waveguide laser is a distributed Bragg grating laser. This has the advantage of providing a DBR laser—comprising a length of optical waveguide comprising optically active material separating two reflective elements in the form of waveguide Bragg gratings—that is easy to fabricate, and for a fibre based laser provides flexibility in the combination of Bragg gratings and fibres.

In an embodiment, the article further comprising an optical component optically coupled to said waveguide laser for isolating said laser wavelength λₛ. The purpose of the optical component is to avoid reflections back into the waveguide laser of light of the laser wavelength.

In an embodiment, further comprising an optical component optically coupled to said pump laser and said waveguide laser for reducing the coupling of light at said laser wavelength reflected back into said waveguide laser from said pump laser. The purpose of the optical component is to avoid reflections back into the waveguide laser of light of the laser wavelength. In an embodiment, the optical component is a WDM.

In an embodiment, optical waveguide laser comprises one or more Rare Earth elements as an optically active material.

In an embodiment, said waveguide laser comprises one or more of the elements from the group of elements comprising Er, Yb, Nd, La, Ho, Dy and Tm. This has the advantage of providing a variety of laser frequencies.

In an embodiment, said waveguide laser is an Er—Yb laser. This has the advantage of providing a waveguide laser with a low phase noise AND a low relative intensity noise. This may be advantageous in applications such as LIDAR or interferometry. In an embodiment, the laser wavelength λₛ=1550 nm and the pump wavelength λₚ =980 or 915 nm.

In an embodiment, said waveguide laser is a fibre laser. This has the advantage of providing lasers with a large flexibility in the design of its characteristics, additionally providing mechanical robustness, relatively small size, relatively low power consumption, etc.

In an embodiment, said fibre laser is based on a silica fibre. This has the advantage of providing a laser system that is compatible with a huge variety of existing optical fibres for communications, sensing and other applications. Alternatively the fibre laser may be based on any other appropriate material system, e.g. polymer, Aluminophosphate, Fluorophosphate, Fluorozirconate (ZBLAN), Phospate, Borate, Tellurite, etc. (cf. e.g. Michel. J. F. Digonnet, “Rare-Earth-Doped Fiber Lasers and Amplifiers”, 2^{nd} edition, 2001, Marcel Dekker, Inc., Chapter 2, p. 17-p. 112, the book being referred to elsewhere in this application as [Digonnet]).

In an embodiment, said fibre laser is based on a double clad fibre, such as a micro-structured double clad fibre, e.g. an air-clad optical fibre. This has the advantage of providing a fibre laser system that is suitable for high-power applications. In the present context, the term an ‘air-clad’ fibre is taken to mean a micro-structured fibre wherein light to be propagated is confined to a part of the fibre within a circumferential distribution of longitudinally extending voids in the cladding of the fibre, cf. e.g. U.S. Pat. No. 5,907,652 or WO-03/019257.

In an embodiment, said waveguide laser is a planar waveguide laser. This has the advantage of providing a potentially compact solution that is suited for integration with other optical components in one or more integrated optical components.

In an embodiment, said planar waveguide laser is based on a silica on silicon technology. This has the advantage of providing a laser system that is based on a well-proven industry-scale technology. Alternatively, the planar waveguide laser may be based on any other appropriate material system, e.g. polymers, Silicon-on-insulator (SOI), Silicon-Oxy-Nitride (SiON), Lithiumniobate (LiNbO3), III-V-semiconductors (incl. GaAs- and InP-based systems), etc.

In a particular embodiment, the system comprises a number of separate optical components connected by lengths of optical waveguides.

In a particular embodiment, the lengths of optical waveguides (e.g. comprising lengths of optical fibre) between at least some of the components of the system are optimized to reduce the pick up of acoustical and mechanical vibrations to improve the phase noise characteristics of the system.

In a particular embodiment, the optical waveguides (e.g. comprising lengths of optical fibre) comprising the waveguide laser and/or the pump laser and/or at least some of the lengths of optical waveguides connecting the components of the system are located on a common support or on separate supports that is/are optimized to minimize the effect of mechanical vibrations from the environment to improve the phase noise characteristics of the system.

In a particular embodiment, the components of the system exclusive of the waveguide laser itself are selected and/or optimized to have a negligible influence on the phase noise characteristics of the laser system, such as accounting for less than 50% of the phase noise, such as less than 20%, such as less than 10%, such as less than 1%.

In a particular embodiment, a feedback grating is located close to the output facet of the pump diode laser, close being defined as less than 1 m, such as less than 0.5 m, such as less than 0.2 m, such as less than 0.1 m, such as less than 0.05 m, such as less than such 0.01 m. Thereby a shortest possible length between the pump diode laser and the feedback grating and the following component, for example the WDM, is provided. This has the advantage of reducing the influence of vibrational pick up of the laser system.

A method of providing a system for exciting laser light at a lasing wavelength λₛ is furthermore provided by the present invention, the method comprising the steps of
a) providing a waveguide laser adapted for exciting laser light at a lasing wavelength λₛ;
b) providing a single frequency laser adapted for exciting pump light at a pump wavelength λₚ;
c) providing that said waveguide laser is pumped with said pump light.

This has the advantage of providing a laser system with a relatively narrow line width and a relatively low phase noise.

In an embodiment, the method further comprises the step of d) providing that reflections of light at said laser wavelength λₛ back into said waveguide laser is minimized. This has the advantage of avoiding damaging or disruptive reflections into the waveguide laser.

In an embodiment, in step a) waveguide laser is a fibre laser and/or in step b) said single frequency laser is a semiconductor laser.

In an embodiment, in step a) said waveguide laser is adapted to comprise Er and/or Yb as optically active materials.

In a particular embodiment, the method further comprises the step of providing a number of separate optical components of the system and of providing lengths of optical waveguides connecting them.

In a particular embodiment, the method further comprises the step of optimizing the lengths of optical waveguides between at least some the components of the system to reduce the pick up of acoustical and mechanical vibrations to improve the phase noise characteristics of the system.

In a particular embodiment, the method further comprises the step of locating the optical waveguides comprising the waveguide laser and/or the pump laser and/or at least some of the lengths of optical waveguides connecting the components of the system on a common support or on separate supports that is/are optimized to minimize the effect of mechanical vibrations from the environment on the phase noise.

In a particular embodiment, the method further comprises the step of selecting and/or optimizing the components of the system exclusive of the waveguide laser itself to have a negligible influence on the phase noise characteristics of the laser system, such as accounting for less than 50% of the phase noise, such as less than 20%, such as less than 10%, such as less than 1%.

In a particular embodiment, the method further comprises the step of locating a feedback grating close to the output facet of the pump diode laser, close being defined as less than 1 m, such as less than 0.5 m, such as less than 0.2 m, such as less than 0.1 m, such as less than 0.05 m, such as less than such 0.01 m, thereby reducing the influence of vibrational pick up of the laser system.

Use of a system according to the invention as described above or in the accompanying claims or a system obtainable by the method according to the invention as described above or in the accompanying claims is moreover provided by the present invention. This has the advantage of enabling applications wherein a low phase noise laser system is required.

In an embodiment, use for coherent LIDAR applications is provided. The invention can advantageously be applied in all LIDAR applications, where a low intensity and frequency or phase noise is required or advantageous, such as in long range LIDAR applications (e.g. wind shear detection).

In an embodiment, use for coherent interferometric applications, such as sub-acoustic and acoustic sensing, is provided.

Further objects of the invention are achieved by the embodiments defined in the dependent claims and in the detailed description of the invention.

It should be emphasized that the term “comprises/comprising” when used in this specification is taken to specify the presence of stated features, integers, steps or components but does not preclude the presence or addition of one or more other stated features, integers, steps, components or groups thereof.

### BRIEF DESCRIPTION OF DRAWINGS

The invention will be explained more fully below in connection with a preferred embodiment and with reference to the drawings in which:

FIG. 1 shows the wavelength spectrum for single and multi mode operation of a pump laser,

FIG. 2 shows intensity noise of a semi-conductor pump laser in single and multi mode operation (same pump laser as FIG. 1),

FIG. 3 shows a beat spectrum of a delayed self-heterodyne linewidth measurement of an erbium-ytterbium co-doped DFB fibre laser pumped with the laser mentioned in FIGS. 1 and 2 operating either single or multimode,

FIG. 4 shows the typical beat spectra of delayed self-heterodyne linewidth measurements of an Er/Yb laser, pumped with commercially available both single frequency and multi mode pump lasers,

FIG. 5 shows the wavelength spectrum of a commercially available single frequency external cavity semi-conductor laser,

FIG. 6 shows an example of fibre laser system according to the invention,

FIG. 7 shows a schematic example of a planar waveguide laser system according to the invention,

FIG. 8 shows a schematic drawing of the delayed heterodyne measurement set-up,

FIG. 9 shows a lasing output power versus diode current response for a particular commercially available single frequency pump diode laser,

FIG. 10 shows a typical RIN spectrum of an Er/Yb fibre laser,

FIG. 11 shows the 20 dB width of the linewidth peak as a function of fibre length between the pump laser diode and the fiber laser for a laser system according to the invention,

FIG. 12 shows the relationship between acoustic frequency νₐ and acoustic wavelength λₐ for acoustic noise picked up by a laser system according to the invention, and

FIG. 13 shows measurements of linewidth at 1585 nm for a laser system according to the invention.

The figures are schematic and simplified for clarity, and they just show details which are essential to the understanding of the invention, while other details are left out.

### MODE(S) FOR CARRYING OUT THE INVENTION

The system can be spliced up in various configurations:
1. Pump-feedback FBG-WDM-fibre laser-isolator (with FBG very close to SCL facet).
2. Pump-fibre-feedback FBG-WDM-fibre laser-isolator.
3. Pump-WDM-fibre laser-feedback FBG-isolator
4. Pump-fibre laser-feedback FBG-isolator

It is noted that the output power of the fiber laser can also be taken out of the system via a back-ward propagating method. In this method the output power is taken out via the extra arm of the WDM. To this arm an isolator should be spliced to avoid back-reflections into the fibre-laser cavity.

Commercial single frequency lasers are available with the configuration mentioned in point ‘1.’ above, e.g. the LU0976M laser from Lumics GmbH, Berlin, Germany.

Single frequency lasers are e.g. discussed in “High-power, ultra-stable, single-frequency operation of a long, doped-fiber external cavity, grating-semiconductor laser”, by F. N. Timofeev and R. Kashyap, Optics Express, vol. 11, no. 6, 24 Mar. 2003, pp. 515-520, in “Narrow linewidth operation of a tunable optically pumped semiconductor laser” by R. H. Abram et al., Optics Express, vol. 12, no. 22, 1 Nov. 2004, pp. 5434-5439, and in “Low-Noise Narrow-Linewidth Fiber Laser at 1550 nm (June 2003)” by C. Spiegelberg et al., J. Lightwave Technology, vol. 22, no. 1, 1 Jan. 2004, pp. 57-62.

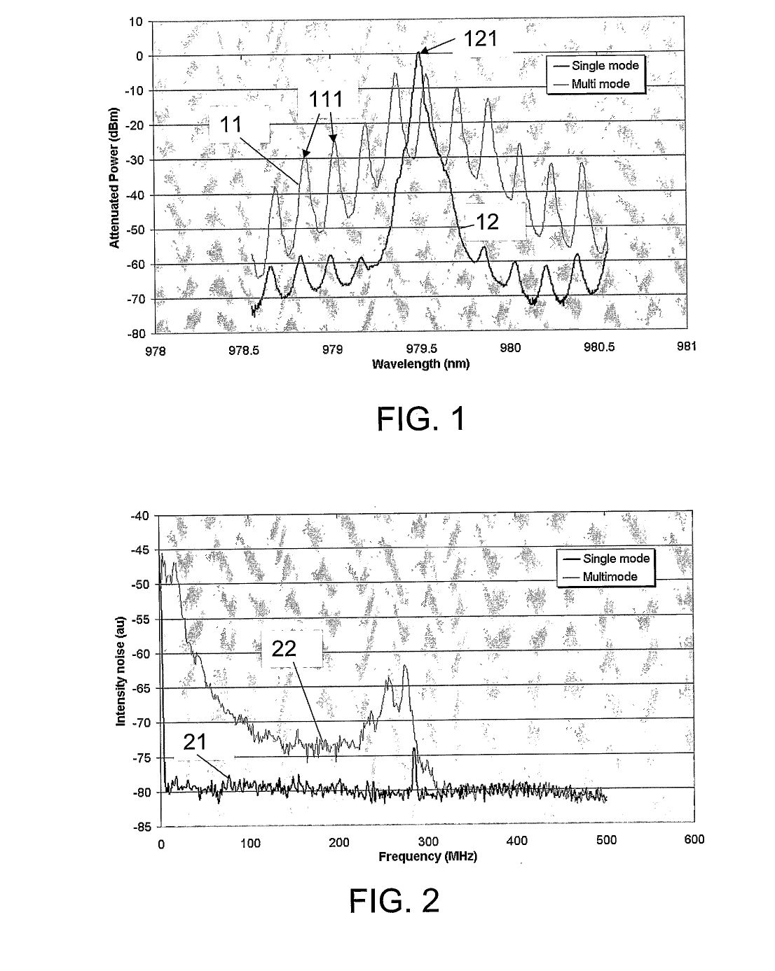

FIG. 1 shows the wavelength spectrum for single and multi mode operation of a pump laser. Even though commercially available 980 nm pump diodes with external feedback FBG show multi mode lasing, the diode can be forced into a single frequency state 12 for specific combinations of diode and temperature current and for a specific fiber-lay (See for example “Detuning characteristics of fibre Bragg grating stabilized 980 nm pump lasers”; S. Mohrdiek, M. Achtenhagen, C. Harder, A. Hardy, OFC Conf. Baltimore, Md., 2000, pp. 168-170). Both the multi 11 and single 12 mode states are shown in FIG. 1. The mode spacing 111 is defined by the cavity length of the diode-chip. The mode spacing of the external cavity is not shown. The single mode spectrum 12 has a narrow peak 121 around 979.5 nm.

FIG. 2 shows intensity noise of a semi-conductor pump laser in single and multi mode operation (same pump laser as FIG. 1). FIG. 2 shows the difference in intensity noise of the semi-conductor laser when it is lasing in either single 21 or multi mode 22. The noise floor of the multi mode laser is much higher than the single mode laser, especially for frequencies lower than 300 MHz.

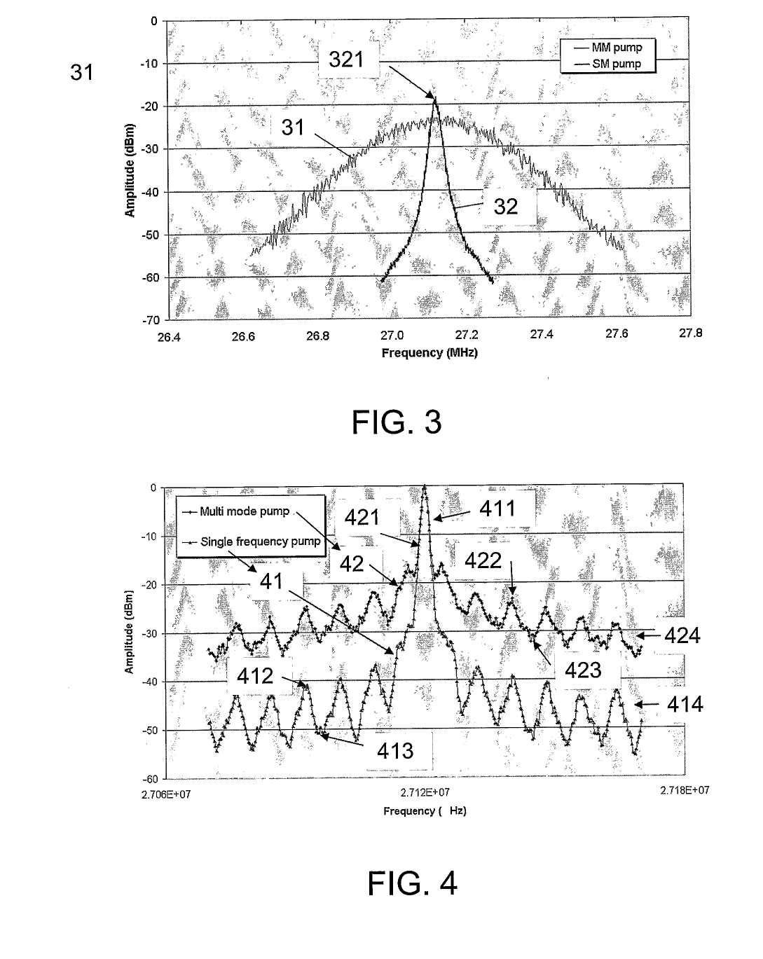

FIG. 3 shows a beat spectrum of a delayed self-heterodyne linewidth measurement of an erbium-ytterbium co-doped DFB fibre laser pumped with the laser mentioned in FIGS. 1 and 2 operating either single or multimode. FIG. 3 shows the difference in beat spectrum when the same fibre laser is pumped with a pump laser operating in either multi 31 or single 32 mode. The figure clearly shows the narrowing of the beat spectrum when the fibre laser is pumped with a single frequency pump laser. The single mode beat spectrum 32 has a narrow peak 321 around 27.15 MHz. Various aspects (including the manufacturing) of rare-earth doped Bragg grating based (e.g. DFB) fibre lasers are discussed in WO-98/36300.

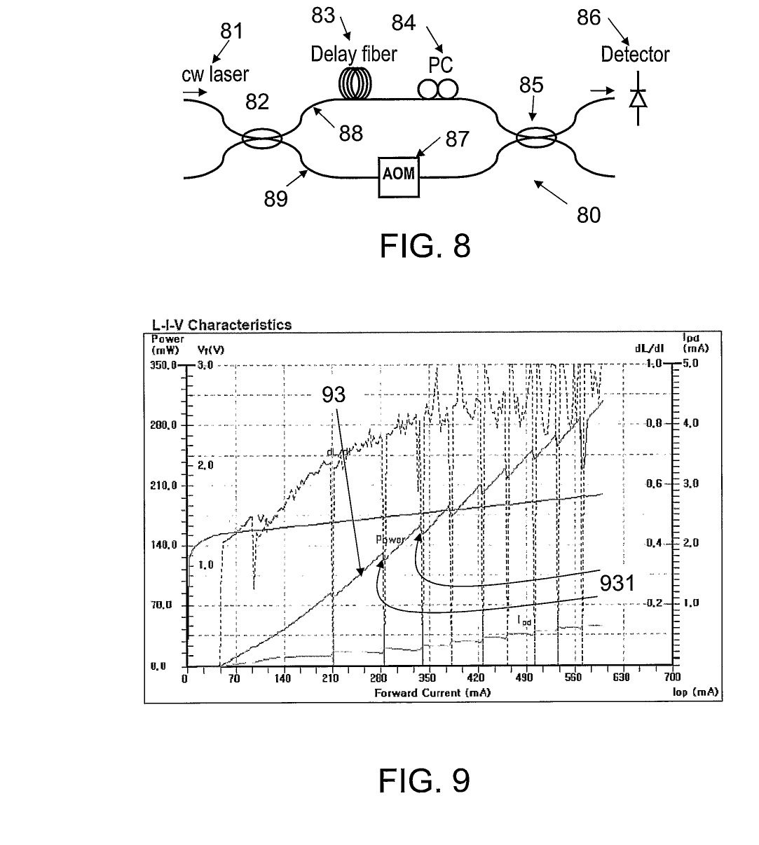

FIG. 4 shows the typical beat spectra 41, 42 of delayed self-heterodyne linewidth measurements of an Er/Yb laser, pumped with commercially available both single frequency (41) and multi mode (42) pump lasers. The linewidth is measured with a delayed self-heterodyne technique (see FIG. 8). The linewidth can be measured from the beat-spectrum of the signal of the ‘local-oscillator’ and the delayed signal. The shown beat-spectra are almost similar to a sinc-function with a delta-peak 411, 421, respectively, in the middle. The large difference between the maximum 412, 422 and minimum 413, 423, respectively, of the sinc-lobes is a proof for a linewidth much smaller than 1 kHz. The difference in the level 414, 424, respectively, of the side-lobes is a measure for the linewidth. FIG. 4 illustrates the lower level 414 when the fibre laser is pumped with a single frequency pump compared with a pump operating in the coherence collapse regime (multi mode) 424.

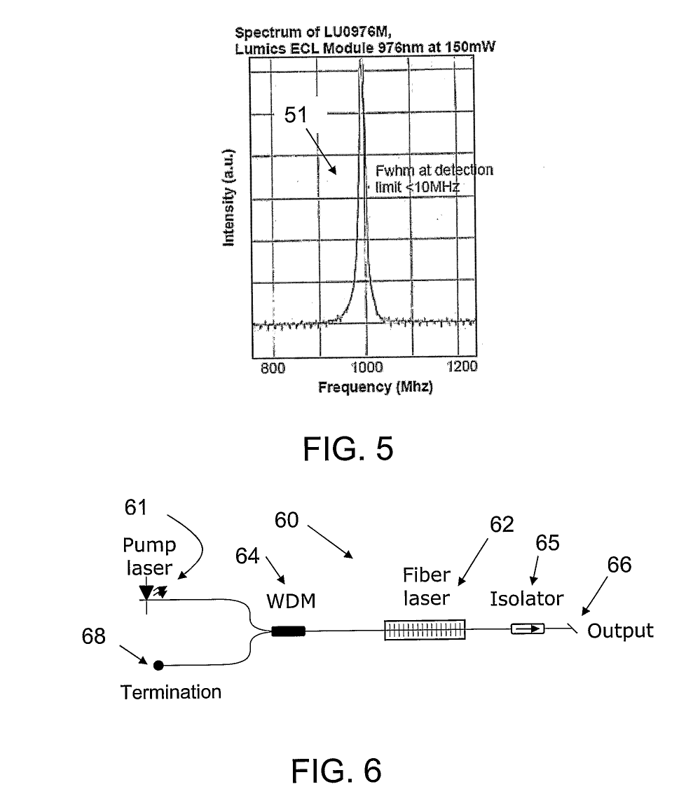

FIG. 5 shows the wavelength spectrum 51 of a commercially available single frequency external cavity semi-conductor laser. A FBG is used as feedback which is placed in the fibre pigtail close to the laser-facet and forces the laser to operate in a single frequency. The single frequency external cavity semi-conductor laser used for the measurements of FIG. 5 is a single frequency 980 nm pump laser (butterfly packaged) available from the German company Lumics GmbH.

FIG. 6 shows an example of fibre laser system 60 according to the invention. A 1550 nm Er/Yb fibre laser 62 is spliced into a system consisting of a 980 nm single frequency pump 61, a 980/1550 WDM 64 and a 1550-isolator 65. The WDM 64 is used to avoid reflections of the fibre laser signal on the pump laser facet back into the fibre laser cavity. The isolator 65 is used to avoid reflections of the fibre laser signal back into the fibre laser cavity from devices connected to the output 66 of the laser system. Unused arms of the WDM may be optically terminated 68. The fibre termination 68, e.g., protects the fibre laser 62 from back reflections. The fibre termination 68 can be replaced with an isolator (65) as used at the ‘output’ 66 in case the fibre laser signal is taken out of the system via a backward propagating method.

Aspects of rare-earth doped fibre lasers are described in a variety of sources, e.g. in [Digonnet].

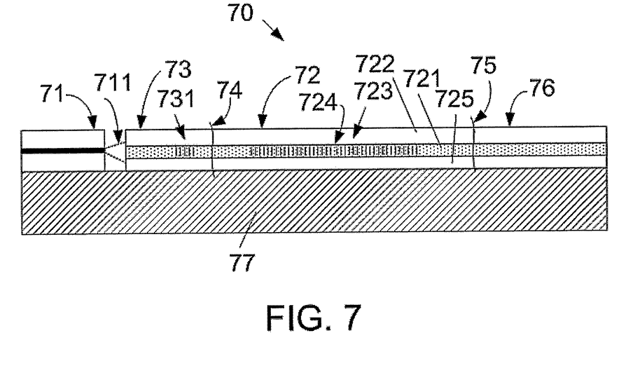

FIG. 7 shows a schematic example of a planar waveguide laser system 70 according to the invention. The system comprises a substrate 87 supporting a laser diode 71. Light 711 from the laser diode is optically coupled to an input planar waveguide section 73 formed on the substrate, the waveguide comprising a base layer, a core region and an upper cladding layer. In the core region, a Bragg grating 731 is dispersed. The input planar waveguide section 73 may function as an external cavity for the semiconductor laser diode 71, together constituting a single frequency pump laser for pumping waveguide laser 72. Light from the single frequency laser (71, 711, 73, 731) is coupled into waveguide laser 72 formed on substrate 77. The waveguide of waveguide laser 72 comprises a base layer 725, a core region 721 and an upper cladding layer 722, the core region comprising an optically active material, such as a rare earth element, e.g. Er and/or Yb. In the core region 721, a Bragg grating 723 comprising a phase shift 724 is dispersed, thereby providing a DFB-type waveguide laser. The DFB-laser 72 is optically coupled to an output waveguide section 76 formed on substrate 77. The output waveguide may e.g. be adapted to be coupled to another optical chip or to an optical fibre and may e.g. comprise coupling elements for adapting the mode size of the waveguides. Curved lines 74 and 75 are intended to indicate that other elements or functional units may be inserted between the input waveguide section 73 and waveguide laser 72 (curved line 74) and/or between waveguide laser 72 and the output waveguide section 76 (curved line 75). Examples of such elements are isolators for preventing reflections of the laser wavelength back into the waveguide laser. The insertion of other components may be appropriate, however.

The Bragg gratings 731, 723 may e.g. be formed by UV-writing in the core region comprising a photosensitive material, e.g. Ge.

A planar laser system according to the invention may be made in a variety of planar technologies based on chemical vapour deposition (including silica on silicon, Silicon-Oxy-Nitride (SiON), etc.), ion exchange, sputtering, etc.

FIG. 8 shows a schematic drawing of the delayed heterodyne measurement set-up.

The fibre laser signal 81 is split into the two arms 88, 89 of a Mach-Zehnder interferometer 80. Part of the signal is used as a ‘local oscillator’ which is mixed with a time-delayed signal at a photo-detector 86. In one of the arms 88 of the interferometer there is a delay fibre 83 of 25 km and a polarisation-controller (PC) 84. In the second arm 89 there is an acoustic modulator (AOM) 87 to shift the frequency of the signal away from the DC component. The signal of the ‘local oscillator’ is shifted in frequency with 27.12 MHz. The output signal of the set-up is collected by a photo detector 86 (TTI TIA-500) and analysed with a RF-spectrum analyser (HP8519E).

FIG. 9 shows the typical lasing output power 93 versus pump current of a commercially available single frequency pump (from Lumics). The lasing output power versus pump current shows a discontinuity for specific pump currents (as e.g. indicated by reference numeral 931), in contrast to multi mode pumps operating in the coherence collapse regime. At the currents where the discontinuity takes place, there is a mode-shift of the laser. The single frequency laser should be operated at a pump current in between the currents 931 at which the mode shift takes place, e.g. at 300 mA for this particular pump-diode.

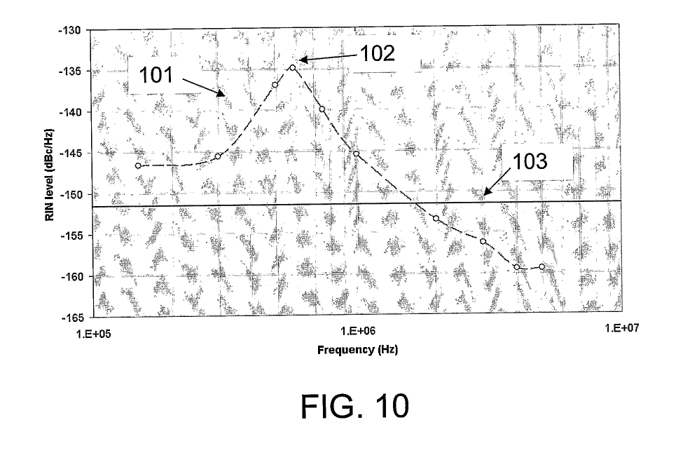

FIG. 10 shows a typical relative intensity noise spectrum of an Er/Yb fibre laser. The relative intensity noise 101 of an Er/Yb co-doped fibre laser shows a RIN peak 102 of approximately −135 dBc/Hz. The RIN is shot-noise limited for RIN levels below 152 dBc/Hz 103.

### EXAMPLE 1

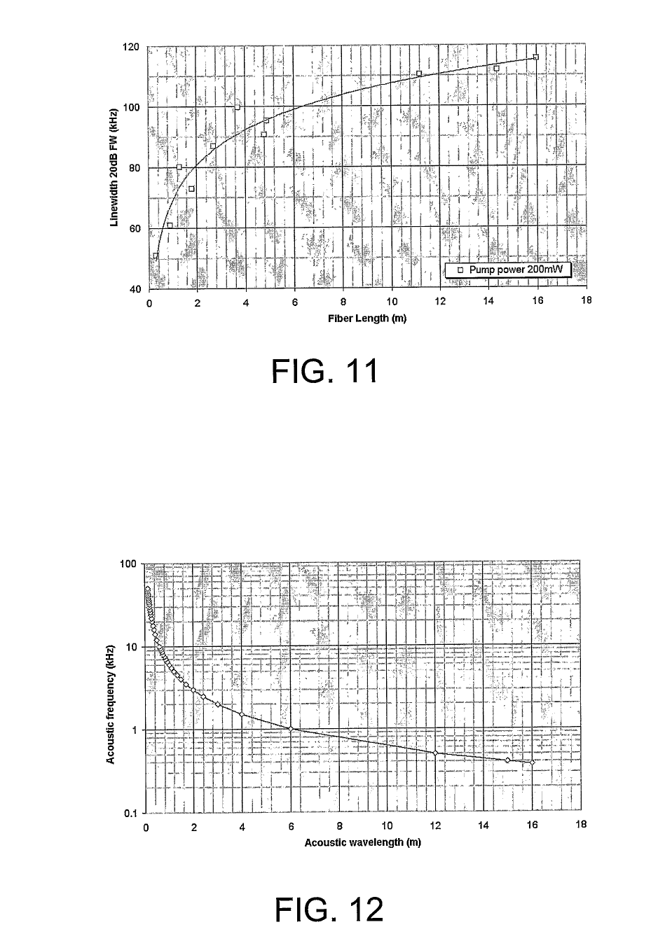

FIG. 11 shows the 20 dB full width of the beat signal (as described in FIG. 3 and FIG. 4) as a function of the fibre length between the pump laser diode and the fiber laser for a laser system according to the invention at a pump power of 200 mW. It follows from these measurements that the line width increases rapidly at relatively smaller fibre lengths (e.g. <2 m) and increases more gradually at relatively larger fibre lengths (e.g. approximately linearly above 6 m).

The measured behaviour could be explained by the pick up of acoustic or mechanical vibrations by the optical fiber (see e.g. “Fiber distributed feedback lasers used as acoustic sensors in air”, S. W. Løvseth et al., Applied Optics, Vol. 38, No. 22, 1999, p. 4821). The relationship between the frequency νₐ and the wavelength λₐ of these vibrations can be expressed by the simple formula: νₐ=cₛ/λₐ with cₛ the speed of light in the optical waveguide medium, here a silica fibre (approximately 6000 m/s). This is plotted in FIG. 12 in case of an acoustical wave picked up by the optical fiber.

FIG. 12 shows the relationship between the frequency νₐ and the wavelength λₐ. Shorter fiber joints show a decreased pick-up of low frequency acoustical or mechanical vibrations, e.g. decreasing the fiber length to 2 m will cut off frequencies below 3 kHz. The abrupt decrease in linewidth for small fiber lengths shows great similarities with the above figure. The shorter the fibre lengths in between the optical components of the laser system, the better the phase noise figure. Here also comes the advantage of using a single frequency laser diode as manufactured by Lumics. The laser diode has a feedback grating positioned very close to the laser facet. In commercially available pump diodes, a feedback grating is normally positioned approximately 1 m away from the laser facet. The length of optical fibre in between the laser diode (FIG. 6, 61) and the WDM (FIG. 6, 66), can therefore be much shorter than in the case of the single frequency laser diode with the feedback grating close to the diode laser facet.

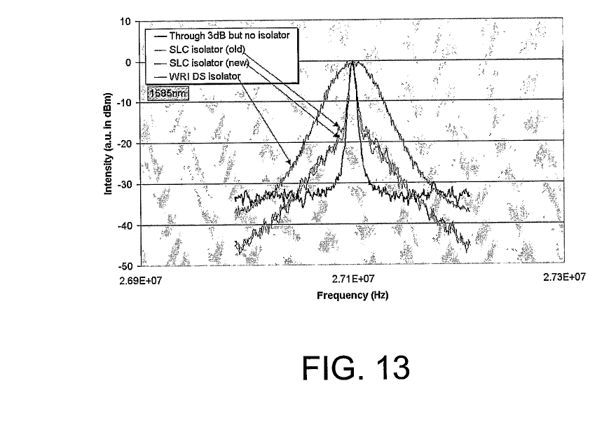

Not only the length of the fibre, but also the type of optical isolater will have influence on the linewidth of the laser system, which is shown in FIG. 13. FIG. 13 shows measurements of linewidth for a laser system at 1585 nm according to the invention. Preferably, the optical isolator is optimized or selected to have a relatively low contribution to the phase noise of the system. Four different graphs are shown.

The graph termed ‘Through 3 dB but no isolator’ illustrates a measurement of the linewidth of the fiber laser without an isolator (65) (FIG. 6) at the output-arm (66).

The graph termed ‘SLC-isolator (old)’ illustrates a situation in which a single stage isolator of the manufacturer SLC (Standard Lightwave Corporation) is used.

The graph termed ‘SLC-isolator (new)’ illustrates a situation in which another single stage isolator of the manufacturer SLC is used. This measurement was used to verify the influence of the type of isolator on the linewidth.

The graph termed ‘WRI DS isolator’ illustrates a situation in which a dual-stage isolator of the manufacturer WRI is used.

An explanation for the observed linewidth broadening or increased phase noise in the case when a dual-stage isolator is used could be mechanical vibrations, which are transferred through the fiber until the point in the optical isolator where the light is coupled out of the fiber into free space (for a schematic figure of an isolator, see for example U.S. Pat. No. 5,546,486). Without knowing the exact configuration of the isolator inside, it is thought that the way the fiber is fixed in the isolator, and herewith the damping of the mechanical vibrations, could cause the linewidth-broadening. The influence of vibrations is already shown by the improved linewidth for decreasing length of the fiber between the optical components (cf. FIG. 11), which is explained by the decreased pick-up of low frequency acoustical or mechanical vibrations.

Phase noise could also be introduced by mechanical or acoustical vibrations in building components of the isolator itself. Differences in the length of the optical path, cause a phase mismatch in the mixing of the two polarisations at the output of the isolator.

The laser system described in the present patent application exhibits an extremely low level of phase noise, which makes the system external noise sources, as for example acoustical and mechanical vibrations, which would normally not be detectable, relatively more important. Therefore the laser system can advantageously be optimized in:

1. The fibre length in between the components.

2. The fibre lay. This can for example be accomplished by laying the optical fibre in a special designed fibre tray. It is important that 1) the fibre is not fixed to the tray and 2) the fibre is positioned in a neutral axis of the tray, i.e. an area which has no or a reduced level of eigen-vibrations (i.e. related to the resonance frequencies of the fiber/tray assembly).

3. The optical components in the fibre laser, e.g. the choice of the optical isolators.

4. The choice of the type of single frequency laser diode: when a feedback grating is used close to the pump diode laser facet, the length between the pump diode laser and the next component can be reduced significantly.

The invention is defined by the features of the independent claim(s). Preferred embodiments are defined in the dependent claims. Any reference numerals in the claims are intended to be non-limiting for their scope.

Some preferred embodiments have been shown in the foregoing, but it should be stressed that the invention is not limited to these, but may be embodied in other ways within the subject-matter defined in the following claims.

1. A system comprising a waveguide laser for exciting laser light at a lasing wavelength λₛ and a pump for pumping the waveguide laser at a pumping wavelength λₚ, wherein the pump is a single frequency laser.

2. A system according to claim 1, wherein said single frequency pump laser is a semiconductor laser.

3. A system according to claim 1, wherein said single frequency pump laser is an external cavity laser.

4. A system according to claim 3, wherein said external cavity comprises an optical waveguide with a Bragg grating.

5. A system according to claim 4, wherein said optical waveguide of said external cavity is a polarization maintaining optical waveguide.

6. A system according to claim 1, wherein said waveguide laser is a Bragg grating laser.

7. A system according to claim 1, wherein said waveguide laser is a distributed feedback laser.

8. A system according to claim 1, wherein said fibre laser is a distributed Bragg grating laser.

9. A system according to claim 1, further comprising an optical component optically coupled to said waveguide laser for isolating said laser wavelength λₛ.

10. A system according to claim 1, further comprising an optical component optically coupled to said pump laser and said waveguide laser for reducing the coupling of light at said laser wavelength reflected back into said waveguide laser from said pump laser.

11. A system according to claim 1, wherein said waveguide laser comprises one or more of the elements from the group of elements comprising Er, Yb, Nd, La, Ho, Dy and Tm.

12. A system according to claim 10, wherein said waveguide laser is an Er—Yb laser.

13. A system according to claim 1, wherein said waveguide laser is a fibre laser.

14. A system according to claim 13, wherein said fibre laser is based on a silica fibre.

15. A system according to claim 13, wherein said fibre laser is based on a double clad fibre, such as a micro-structured double clad fibre, e.g. an air-clad optical fibre.

16. A system according to claim 1, wherein said waveguide laser is a planar waveguide laser.

17. A system according to claim 15, wherein said planar waveguide laser is based on a silica on silicon technology.

18. A system according to claim 1, wherein the system comprises a number of separate optical components connected by lengths of optical waveguides.

19. A system according to claim 18 wherein the lengths of optical waveguides between at least some the components of the system are optimized to reduce the pick up of acoustical and mechanical vibrations to improve the phase noise characteristics of the system.

20. A system according to claim 18 wherein the optical waveguides comprising the waveguide laser and/or the pump laser and/or at least some of the lengths of optical waveguides connecting the components of the system are located on a common support or on separate supports that is/are optimized to minimize the effect of mechanical vibrations from the environment.

21. A system according to claim 18, wherein the components of the system exclusive of the waveguide laser itself are selected and/or optimized to have a negligible influence on the phase noise characteristics of the laser system, such as accounting for less than 50% of the phase noise, such as less than 20%, such as less than 10%, such as less than 1%.

22. A system according to claim 2, wherein a feedback grating is located close to the output facet of the pump diode laser, close being defined as less than 1 m, such as less than 0.5 m, such as less than 0.2 m, such as less than 0.1 m, such as less than 0.05 m, such as less than such 0.01 m.

23. A method of providing a system for exciting laser light at a lasing wavelength λₛ, the method comprising the steps of
a) providing a waveguide laser adapted for exciting laser light at a lasing wavelength λₛ;
b) providing a single frequency laser adapted for exciting pump light at a pump wavelength λₚ;
c) providing that said waveguide laser is pumped with said pump light.

24. A method according to claim 23 wherein said method further comprises the step of
d) providing that reflections of light at said laser wavelength λₛ back into said waveguide laser is minimized.

25. A method according to claim 23 wherein in step a) waveguide laser is a fibre laser and/or in step b) said single frequency laser is a semiconductor laser.

26. A method according to claim 23, wherein in step a) said waveguide laser is adapted to comprise Er and/or Yb as optically active materials.

27. A method according to claim 23, the method further comprising the step of providing a number of separate optical components of the system and of providing lengths of optical waveguides connecting them.

28. A method according to claim 27, the method further comprising the step of optimizing the lengths of optical waveguides between at least some the components of the system to reduce the pick up of acoustical and mechanical vibrations to improve the phase noise characteristics of the system.

29. A method according to claim 27, the method further comprising the step of locating the optical waveguides comprising the waveguide laser and/or the pump laser and/or at least some of the lengths of optical waveguides connecting the components of the system on a common support or on separate supports that is/are optimized to minimize the effect of mechanical vibrations from the environment.

30. A method according to claim 27, the method further comprising the step of selecting and/or optimizing the components of the system exclusive of the waveguide laser itself to have a negligible influence on the phase noise characteristics of the laser system, such as accounting for less than 50% of the phase noise, such as less than 20%, such as less than 10%, such as less than 10%.

31. A method according to claim 25, the method further comprising the step of locating a feedback grating close to the output facet of the pump diode laser, close being defined as less than 1 m, such as less than 0.5 m, such as less than 0.2 m, such as less than 0.1 m, such as less than 0.05 m, such as less than such 0.01 m, thereby reducing the influence of vibrational pick up of the laser system.

32. Use of a system according to comprising a waveguide laser for exciting laser light at a lasing wavelength λₛ and a pump for pumping the waveguide laser at a pumping wavelength λₚ, wherein the pump is a single frequency laser or a system obtainable by the method according to claim 23.

33. Use according to claim 32 for coherent LIDAR applications.

34. Use according to claim 32 for coherent interferometric applications, such as sub-acoustic and acoustic sensing.
